(19) United States
(12) Patent Application Publication
(10) Pub. No.: US 2026/0212897 A1
(43) Pub. Date: Jul. 23, 2026

(54) SEMICONDUCTOR DEVICE AND METHOD OF MANUFACTURING SAME

(71) Applicant: Taiwan Semiconductor Manufacturing Company, LTD., Hsinchu (TW)

(72) Inventors: Tzu Jung Tien, Hsinchu (TW); Cheung Cheng, Hsinchu (TW); Wen-Chih Chiang, Hsinchu (TW)

(21) Appl. No.: 19/028,551

(22) Filed: Jan. 17, 2025

(51) Int. Cl. G11C 5/06; H10B 20/00

(52) U.S. Cl. CPC G11C 5/06; H10B 20/387

(57) ABSTRACT

In a method for fabricating an integrated circuit, logic circuitry devices are formed in and/or on a semiconductor substrate. A metallization stack is formed on the semiconductor substrate. The metallization stack includes patterned metal layers and vias embedded in a dielectric material. A read-only memory (ROM) transistor array is formed on the metallization stack. The ROM transistor array is electrically connected with vias of the metallization stack. The ROM transistor array may include transistor channels and source and drain lines formed from an amorphous silicon layer that is deposited at a temperature of 450^{o}C or lower. ROM transistor array fabrication steps performed after depositing the amorphous silicon layer may also be performed at a temperature of 450^{o}C or lower.

### BACKGROUND

The following relates to read-only memory (ROM) devices and arrays, integrated circuits (ICs) with ROM, methods of fabricating the foregoing, and to the like.

A ROM is a type of nonvolatile memory employed in a wide range of ICs. A ROM programmed with stored values at the time of IC fabrication can serve as storage for software, firmware, IC configuration data, and so forth. A ROM can occupy substantial area of the IC chip or die, which can be problematic when endeavoring to miniaturize an IC chip or die for applications such as cellular telephones.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A and 1B diagrammatically illustrate the footprint and a cut view, respectively, of an IC including logic circuitry devices and a ROM transistor array in one configuration; while FIGS. 1C and 1D diagrammatically illustrate the footprint and a cut view, respectively, of an IC including logic circuitry devices and a ROM transistor array in another, more compact, configuration.

FIGS. 2A and 2B diagrammatically illustrate top and cut views, respectively, of an IC with compact configuration of FIGS. 1C and 1D.

FIGS. 3A, 3B, 3C, 3D, 3E, 3F, 3G, 3H, and 3I diagrammatically illustrate fabrication of an IC with the compact configuration of FIGS. 1C and 1D by way of cut views the IC under fabrication at successive steps of the fabrication process.

FIG. 4 diagrammatically illustrates a cut view of an IC with compact configuration of FIGS. 1C and 1D according to another embodiment.

FIGS. 5A and 5B diagrammatically illustrate top and cut views, respectively, of an IC with compact configuration of FIGS. 1C and 1D according to another embodiment.

FIG. 6 diagrammatically illustrates a cut view of an IC with compact configuration of FIGS. 1C and 1D according to another embodiment.

FIGS. 7A and 7B diagrammatically illustrate top and cut views of an IC with compact configuration of FIGS. 1C and 1D according to further embodiments.

### DETAILED DESCRIPTION

The following disclosure provides many different embodiments, or examples, for implementing different features of the provided subject matter. Specific examples of components and arrangements are described below to simplify the present disclosure. These are merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

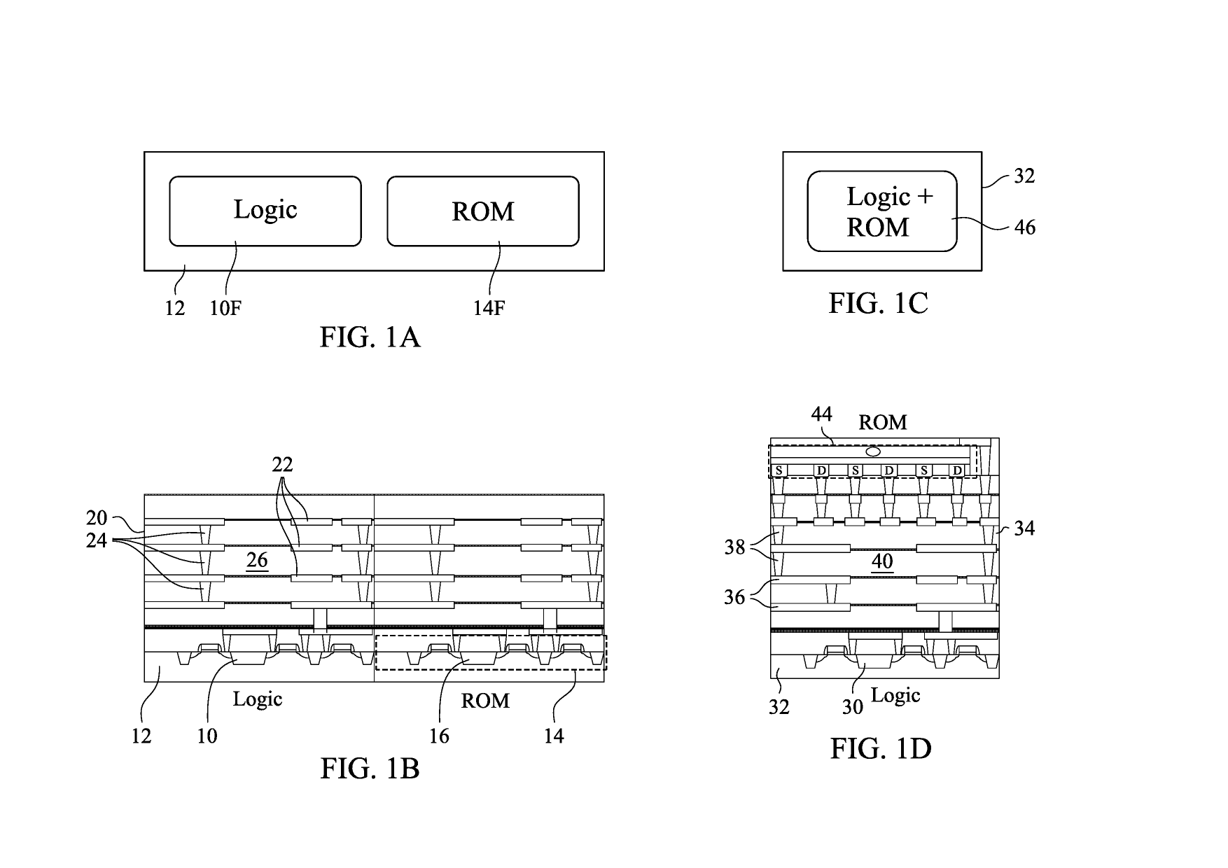

FIGS. 1A and 1B diagrammatically illustrate the footprint and a cut view, respectively, of an integrated circuit (IC) including logic circuitry devices 10 formed in and/or on a semiconductor substrate 12, and a random access memory (ROM) transistor array 14 formed in and/or on the semiconductor substrate. Referring to FIG. 1A, the footprint of the logic circuitry devices 10 is indicated by reference number 10F, and the footprint of the ROM transistor array 14 is indicated by reference number 14F. The footprint 10F of the logic circuitry devices 10 is the surface area of the semiconductor substrate 12 occupied by the logic circuitry devices 10; and likewise the footprint 14F of the ROM transistor array 14 is the surface area of the semiconductor substrate 12 occupied by the ROM transistor array 14. Hence, FIG. 1A constitutes a diagrammatic top view of the IC showing the outline of the area (i.e., footprint 10F) of the logic circuitry devices 10 and the outline of the area (i.e., footprint 14F) of the ROM transistor array 14. The semiconductor substrate 12 may, by way of some nonlimiting illustrative examples, comprise a silicon substrate such as a silicon wafer, or a silicon-on-insulator (SOI) substrate such as an SOI wafer, or a substrate of another semiconductor such as a gallium arsenide (GaAs) substrate or a germanium (Ge) substrate.

As seen in the cut view of FIG. 1B, the logic circuitry devices 10 may comprise FinFETs, gate-all-around (GAA) transistors, nanowire transistors, planar field effect transistors (FETs) such as planar MOSFETs, complementary field effect transistors (CFETs), and/or other types of transistors, capacitors, and/or so forth. The logic circuitry devices 10 are formed or fabricated in and/or on the semiconductor substrate 12. The ROM transistor array 14 includes an array of transistors 16, also referred to herein as ROM transistors 16 to distinguish from transistors of the logic circuitry devices 10. The ROM transistors 16 may, by way of nonlimiting illustrative example, include FinFETs, GAA transistors, nanowire transistors, planar FETs such as planar MOSFETs, CFETs, and/or so forth, also formed or fabricated in and/or on the semiconductor substrate 12. Although not shown in the cut view of FIG. 1B, the transistors 16 of the ROM transistor array 14 form a two-dimensional array of ROM transistors 16. As further seen in FIG. 1B, a metallization stack 20 is disposed on the semiconductor substrate 12, and more particularly over the logic circuitry devices 10 and the ROM transistor array 14. The metallization stack 20 includes patterned metal layers 22 and vias 24 embedded in a dielectric material 26. The patterned metal layers 22 and vias 24 provide electrical interconnection of the logic circuitry devices 10 and electrical interconnection of the ROM transistor array 14.

As best seen in FIG. 1A, the footprint 10F of the logic circuitry devices 10 and the footprint 14F of the ROM transistor array 14 do not overlap. With the configuration of the IC of FIGS. 1A and 1B, both the logic circuitry devices 10 and the ROM transistor array 14 are fabricated in and/or on a semiconductor substrate, which makes it difficult or impossible for their footprints to overlap. Consequently, the total IC footprint is the combined footprints 10F and 14F of the logic circuitry devices 10 and the ROM transistor array 14.

FIGS. 1C and 1D diagrammatically illustrate the footprint and a cut view, respectively, of an IC according to another embodiment. The IC of FIGS. 1C and 1D includes logic circuitry devices 30 formed in and/or on a semiconductor substrate 32. The logic circuitry devices 30 may comprise FinFETs, GAA transistors, nanowire transistors, planar FETs such as planar MOSFETs, CFETs, and/or other types of transistors, capacitors, and/or so forth. The semiconductor substrate 32 may, by way of some nonlimiting illustrative examples, comprise a silicon substrate such as a silicon wafer, or a SOI substrate such as an SOI wafer, or a substrate of another semiconductor such as a GaAs substrate or a Ge substrate. A metallization stack 34 is disposed on the semiconductor substrate 32, and including patterned metal layers 36 and vias 38 embedded in a dielectric material 40.

Unlike the embodiment of FIGS. 1A and 1B, in the embodiment of FIGS. 1C and 1D a ROM transistor array 44 is disposed on the metallization stack 34 with the metallization stack 34 interposed between the ROM transistor array 44 and the logic circuitry devices 30. Hence, the logic circuitry devices 30 and the ROM transistor array 44 are spaced apart vertically (where the vertical direction is transverse to the surface of the substrate 32, and the vias 38 extend along the vertical direction in the cut view of FIG. 1D). The metallization stack 34 electrically connects the ROM transistor array 44 and the logic circuitry devices 30.

Because of this vertical arrangement, in the embodiment of FIGS. 1C and 1D the logic circuitry devices 30 and the ROM transistor array 44 have an overlapping footprint 46 diagrammatically shown in FIG. 1C, which is smaller than the combined footprints 10F and 14F of the logic circuitry devices 10 and ROM transistor array 14 of the embodiment of FIGS. 1A and 1B. In general, due to the vertical arrangement in which the logic circuitry devices 30 and the ROM transistor array 44 are spaced apart vertically by the interposed metallization stack 34, the footprint of the ROM transistor array 44 can at least partly overlap the footprint of the logic circuitry devices 30. In some embodiments, the ROM transistor array footprint of the ROM transistor array 44 may be equal to (i.e., coextensive with) or entirely inside the logic footprint of the logic circuitry devices 30.

Thus, for logic circuitry devices with a given footprint and a ROM transistor array with a given footprint, an IC fabricated with the vertical arrangement of FIGS. 1C and 1D advantageously has a smaller combined footprint for the combination of the logic circuitry devices and the ROM transistor array, when compared with an IC fabricated with the lateral arrangement of FIGS. 1A and 1B. This advantageously provides more efficiently utilization of the chip area (that is, the area on the substrate in which the IC can be fabricated).

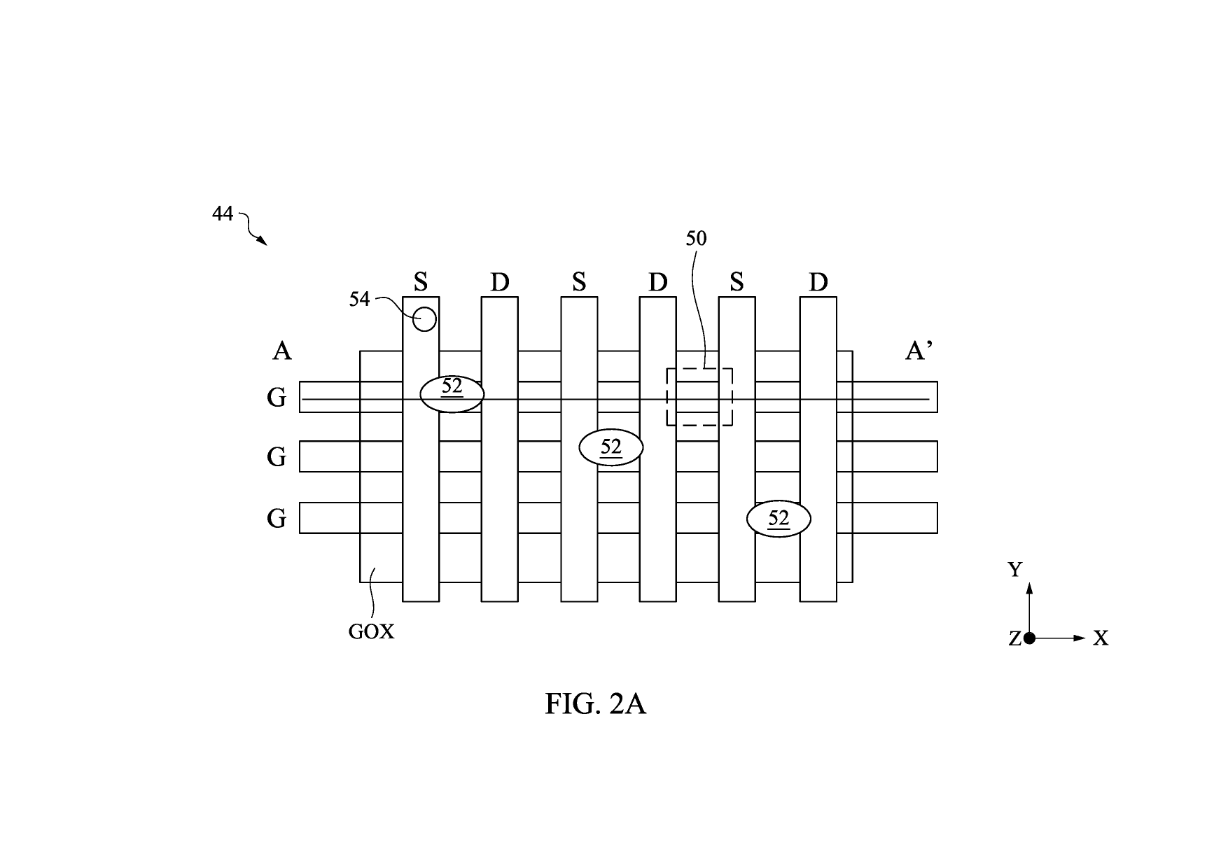

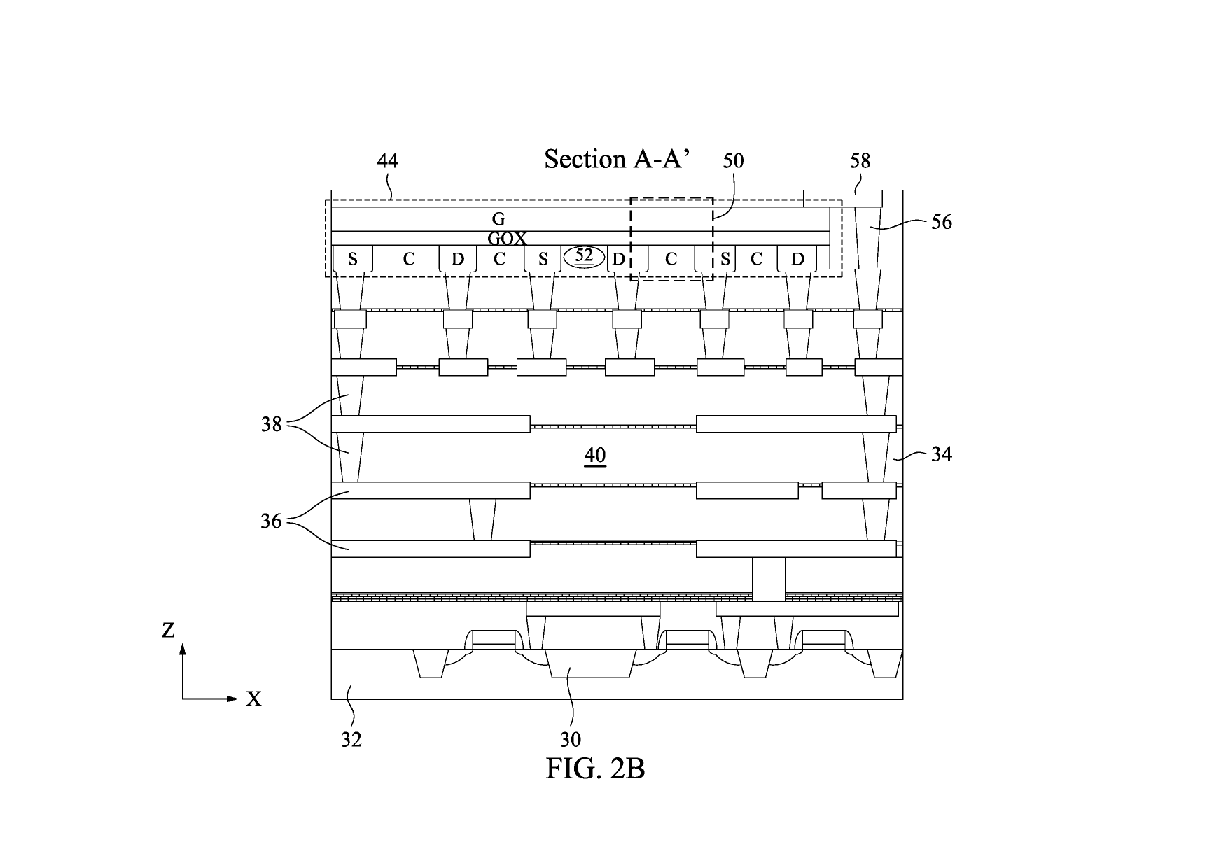

FIGS. 2A and 2B diagrammatically illustrate top and cut views, respectively, of an IC with compact configuration of FIGS. 1C and 1D. FIG. 2B is a cut taken along the Cut plane A-A’ indicated in FIG. 2A. FIG. 2B corresponds to an enlarged view of FIG. 1D, and includes the previously described logic circuitry devices 30 (e.g., the logic circuitry devices 30 may comprise FinFETs, GAA transistors, nanowire transistors, planar FETs such as planar MOSFETs, CFETs, and/or other types of transistors, capacitors, and/or so forth) formed in and/or on the semiconductor substrate 32 (which may, by way of some nonlimiting illustrative examples, comprise a silicon substrate or wafer, SOI substrate or wafer, or a substrate or wafer of another semiconductor such as a GaAs or Ge), a metallization stack 34 disposed on the semiconductor substrate 32 (and more particularly on the logic circuitry devices 30) and including patterned metal layers 36 and vias 38 embedded in a dielectric material 40, and the ROM transistor array 44.

Referencing first the cut view of FIG. 2B, the ROM transistor array 44 includes transistor channels C, source lines S and drain lines D, a gate oxide Gox, and gate lines G. In some embodiments, the channels C, source lines S, and drain lines D are formed from an amorphous silicon (a-Si) layer, with the source and drain lines S and D being formed by targeted doping of the amorphous silicon layer to make the source and drain lines S and D more electrically conductive than the remainder of the amorphous silicon layer which forms the channels C. The dopants used to form the source and drain lines S and D when they are fabricated of amorphous silicon may, by way of nonlimiting illustrative example, be nitrogen, phosphorous, arsenic, tin, bismuth, oxygen, nitrogen, sulfur, selenium, tellurium, fluorine, chlorine, bromine, iodine, boron, aluminum, gallium, indium, titanium, tantalum, or so forth. The gate oxide Gox is deposited on the amorphous silicon layer, and comprises a dielectric material such as (by way of nonlimiting illustrative example) silicon dioxide (SiO₂), silicon oxynitride (SiON), silicon nitride (SiN), hafnium oxide (HfO), or a high-k dielectric material. The gate lines G in some embodiments comprise a polycrystalline silicon layer (also referred to herein as a polysilicon layer or poly-Si layer) disposed on the gate oxide Gox and patterned to form the gate lines.

FIG. 2A which shows a top view of the topmost ROM transistor array 44, illustrating the relative orientations of the source and drain lines S and D and the gate lines G. To assist in description and without loss of generality, a Cartesian direction system is shown in FIGS. 2A and 2B indicating X-, Y-, and Z-directions. As seen in FIG. 2A, the gate lines G are parallel with the X-direction while the source and drain lines S and D are parallel with the transverse Y-direction. The source lines S and drain lines D are parallel with each other, and the gate lines G are transverse (i.e., orthogonal) to the source and drain lines S and D. Using this Cartesian direction system, the cut plane A-A’ of FIG. 2B is an X-Z plane. Comparing FIGS. 2A and 2B, it is seen that the transistor channels C shown in FIG. 2B are oriented along the X-direction parallel with the gate lines G, with each transistor channel C having a corresponding segment of an aligned gate line G disposed proximate to it, and spaced apart by the gate oxide Gox.

Thus, the ROM transistor array 44 is disposed in an X-Y plane, with each ROM transistor connected with a source line S, a drain line D, and having a gate comprising the corresponding segment of an aligned gate line G spaced apart therefrom by the gate oxide Gox. One illustrative ROM transistor 50 of the ROM transistor array 44 is indicated by a dashed box in FIGS. 2A and 2B. As seen in FIG. 2B, the metallization stack 34 provides electrical interconnection between the logic circuitry devices 30 formed in and/or on a semiconductor substrate 32 and the ROM transistor array 44.

In the embodiment of FIGS. 2A and 2B, a given ROM transistor is programmed to store either a logical “1” or a logical “0” by whether its threshold voltage (Vt) is adjusted by a targeted dopant implant 52. In the illustrative example of FIG. 2B, one illustrative targeted dopant implant 52 is deposited in the channel C of the ROM transistor. FIG. 2A shows three examples of targeted dopant implants 52 to program values in a corresponding three ROM transistors. The ROM transistors without a targeted dopant implant 52 will have a first threshold voltage, while the ROM transistors with a targeted dopant implant 52 will have a second threshold voltage that is different from the first threshold voltage. By changing the threshold voltage of the ROM transistor using the targeted dopant implant 52, the electrical current driven through the channel C of the ROM transistor in response to a chosen applied voltage is changed. This is merely one nonlimiting illustrative example, and more generally the stored logical value can be read in other ways (e.g., chosen applied electrical current and read out the voltage).

In some examples, the default logical value stored in a ROM transistor is logical “0”, and the targeted dopant implant 52 changes the threshold voltage Vt so that the ROM transistor with the targeted dopant implant 52 stores a logical “1”. However, the designation of the logical values stored in a ROM transistor with or without a targeted dopant implant 52 depends on design-specific aspects such as the transistor characteristics of the ROM transistors, the implant dose and dopant type (n-type dopant or p-type dopant) of the targeted dopant implants 52, and how the readouts of the ROM transistors are interpreted by the logic circuitry implemented by the logic circuitry devices 30. The ROM transistor array 44 is a nonvolatile read-only memory (ROM) because once the targeted dopant implants 52 are applied to the chosen ROM transistors, the values stored in the ROM transistors of the ROM transistor array 44 are static and do not depend on maintaining electrical power to the ROM transistor array 44. Hence, the ROM transistor array 44, once programmed by the targeted dopant implants 52, can advantageously serve as storage for software, firmware, IC configuration data, and/or so forth. As previously noted, in the vertical design of FIGS. 2A and 2B, the IC is advantageously provided with this software, firmware, IC configuration data with the combined footprint 46 (see FIG. 1C) which is smaller than the total footprint 10F and 14F of a laterally arranged IC (see FIGS. 1A and 1B).

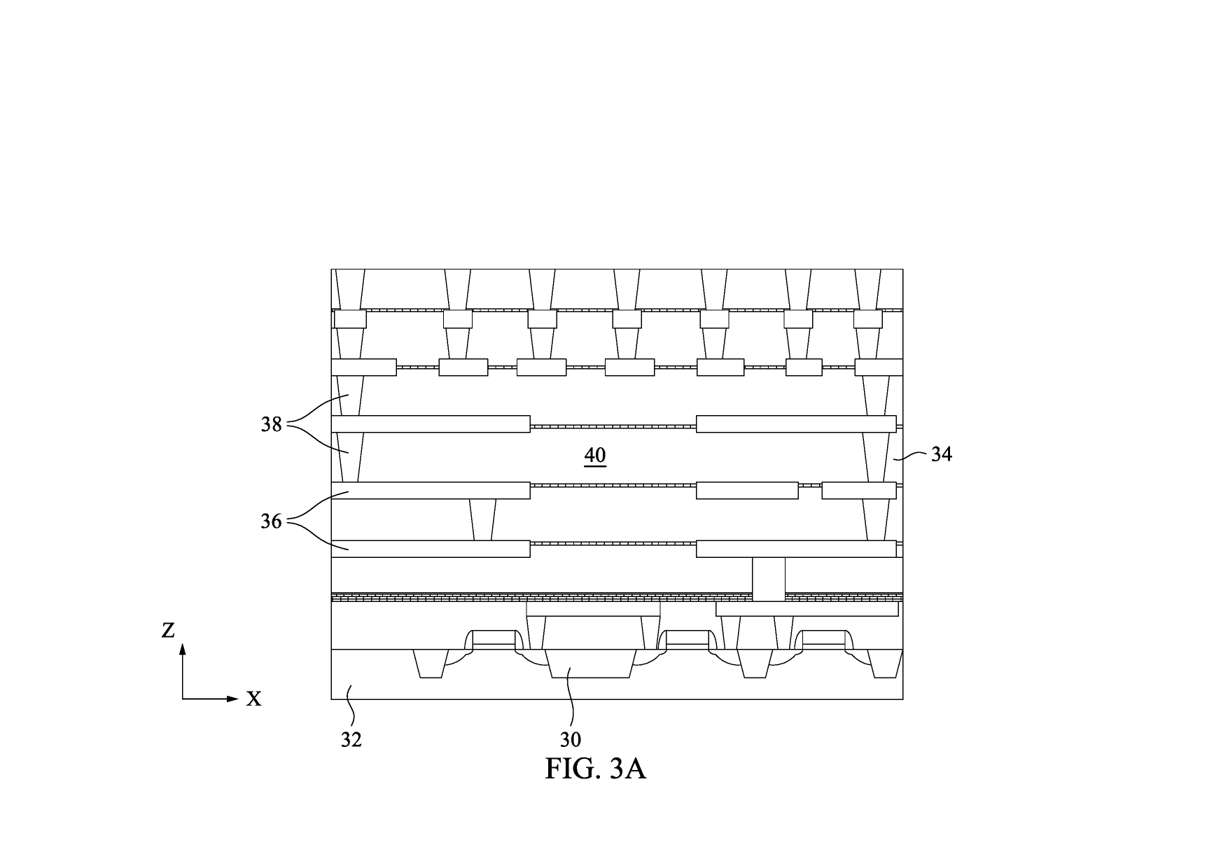

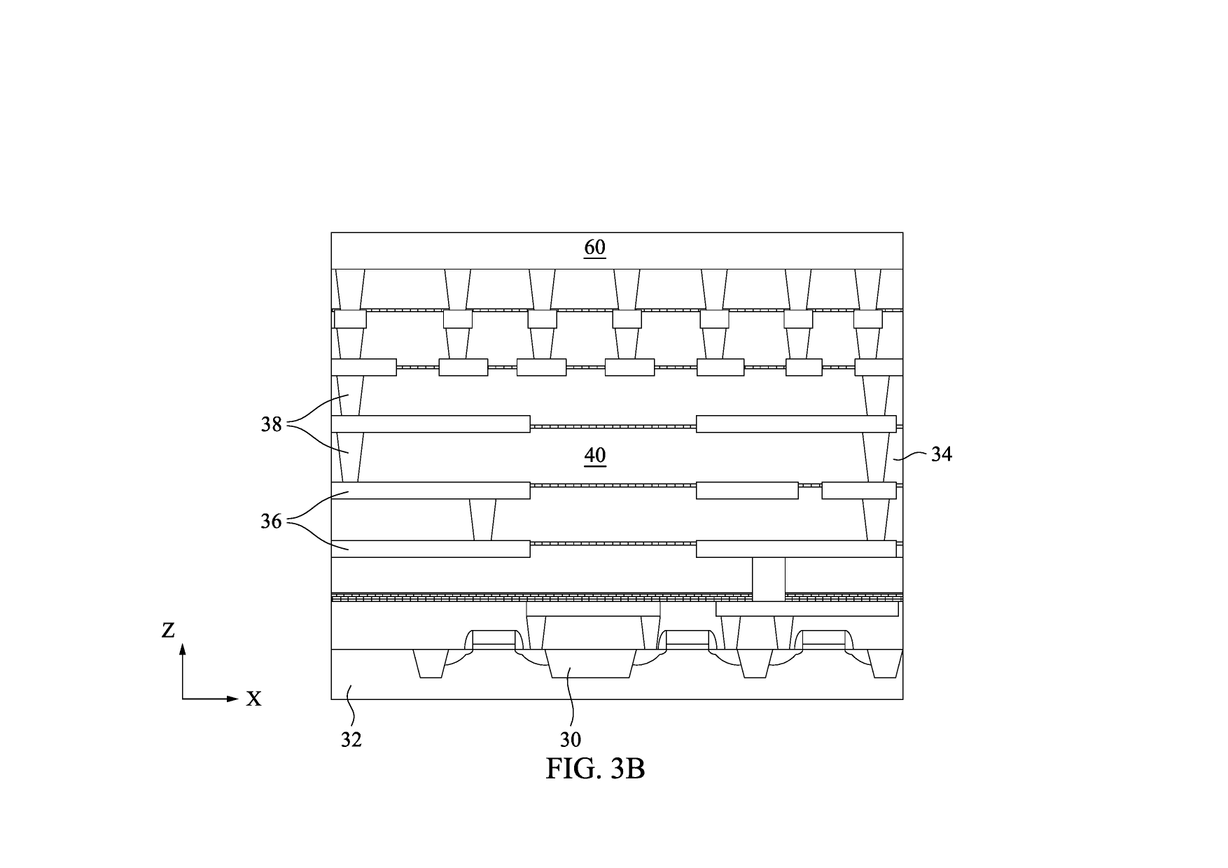

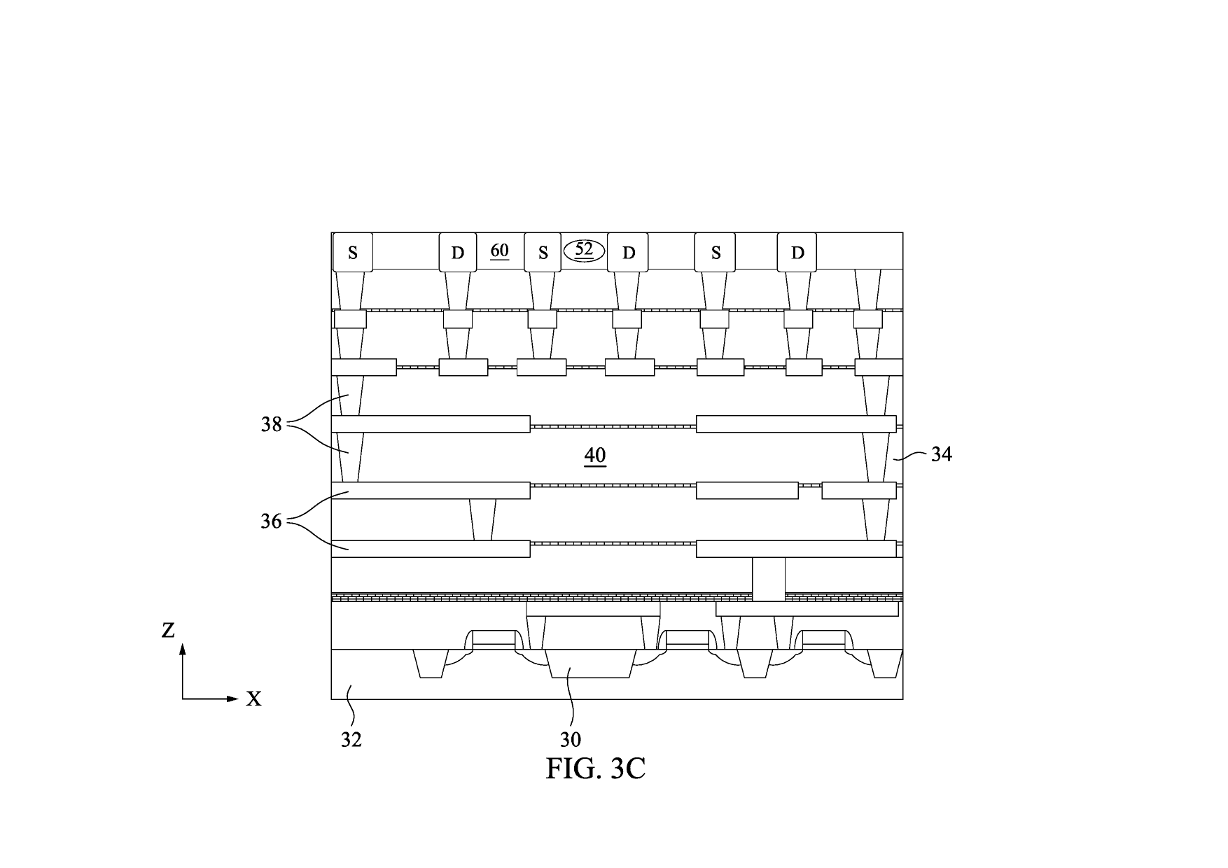

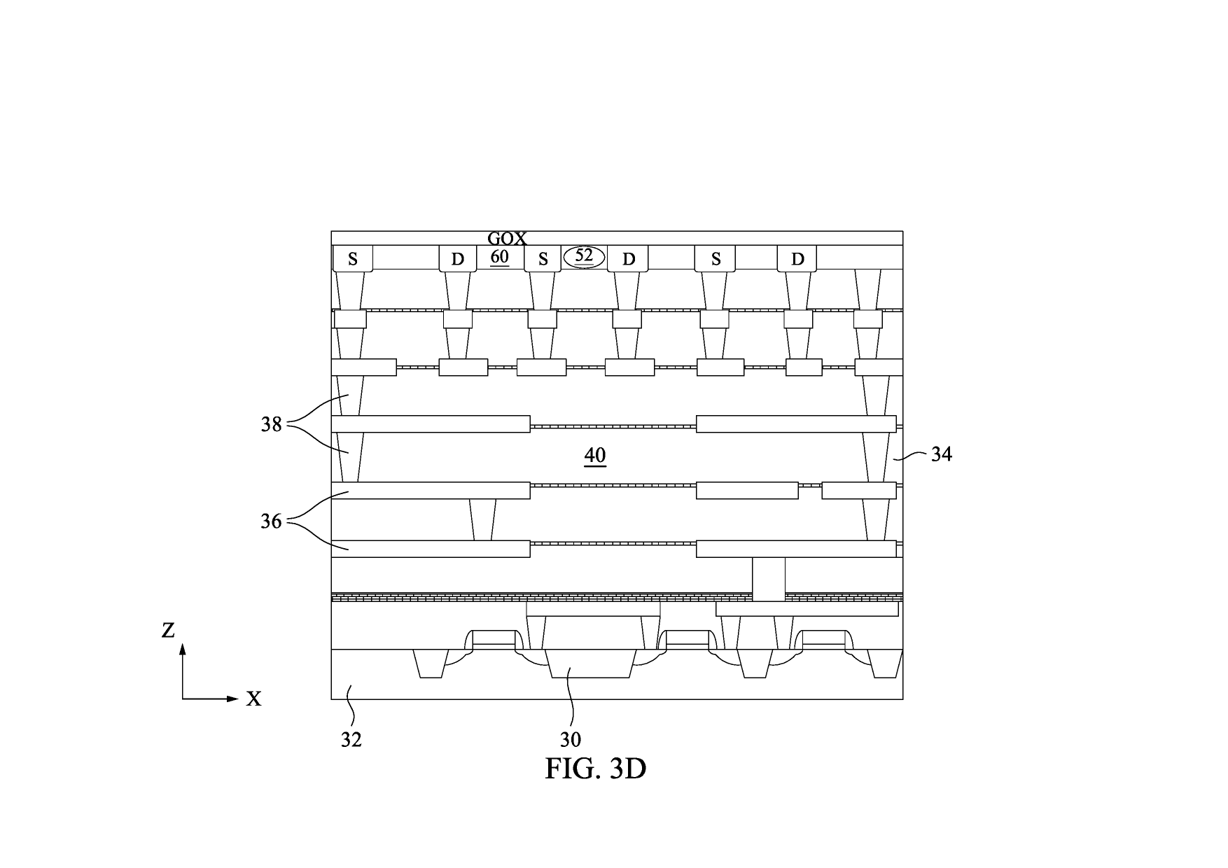

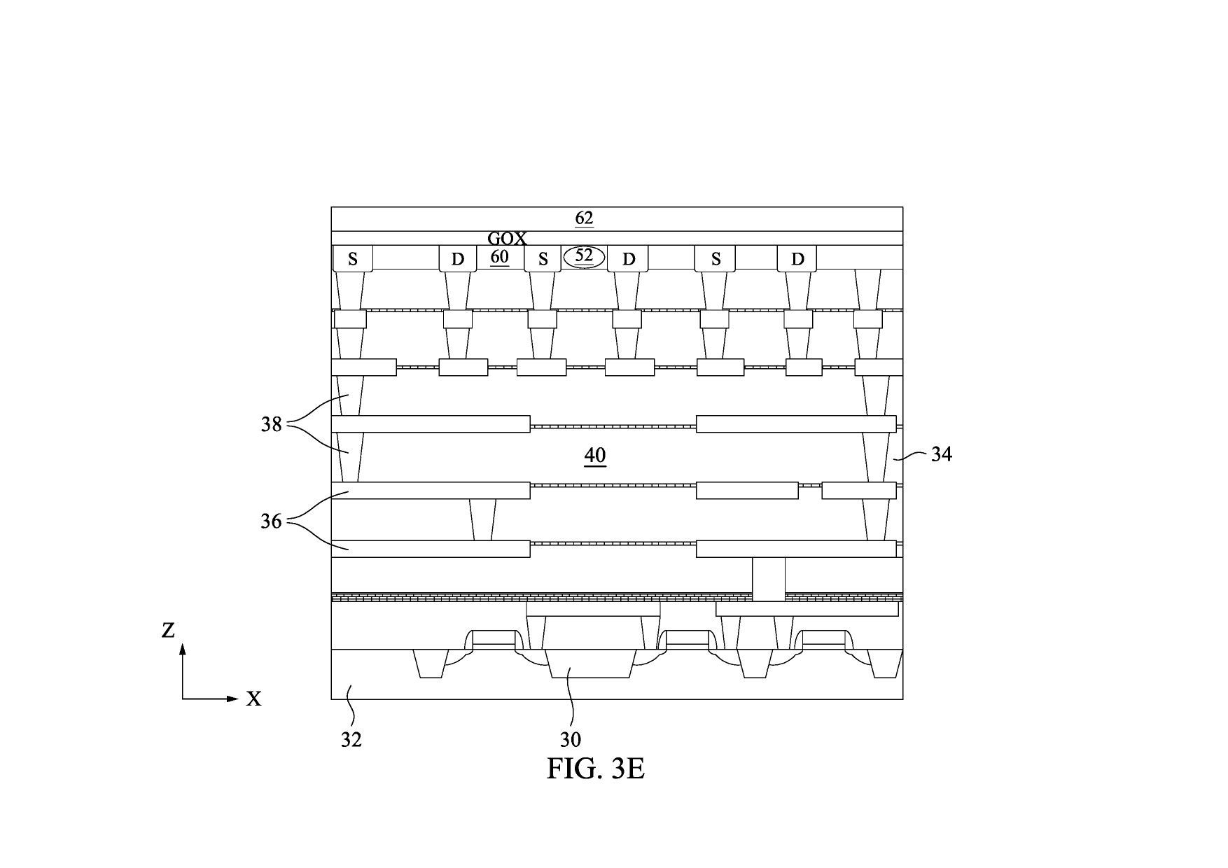

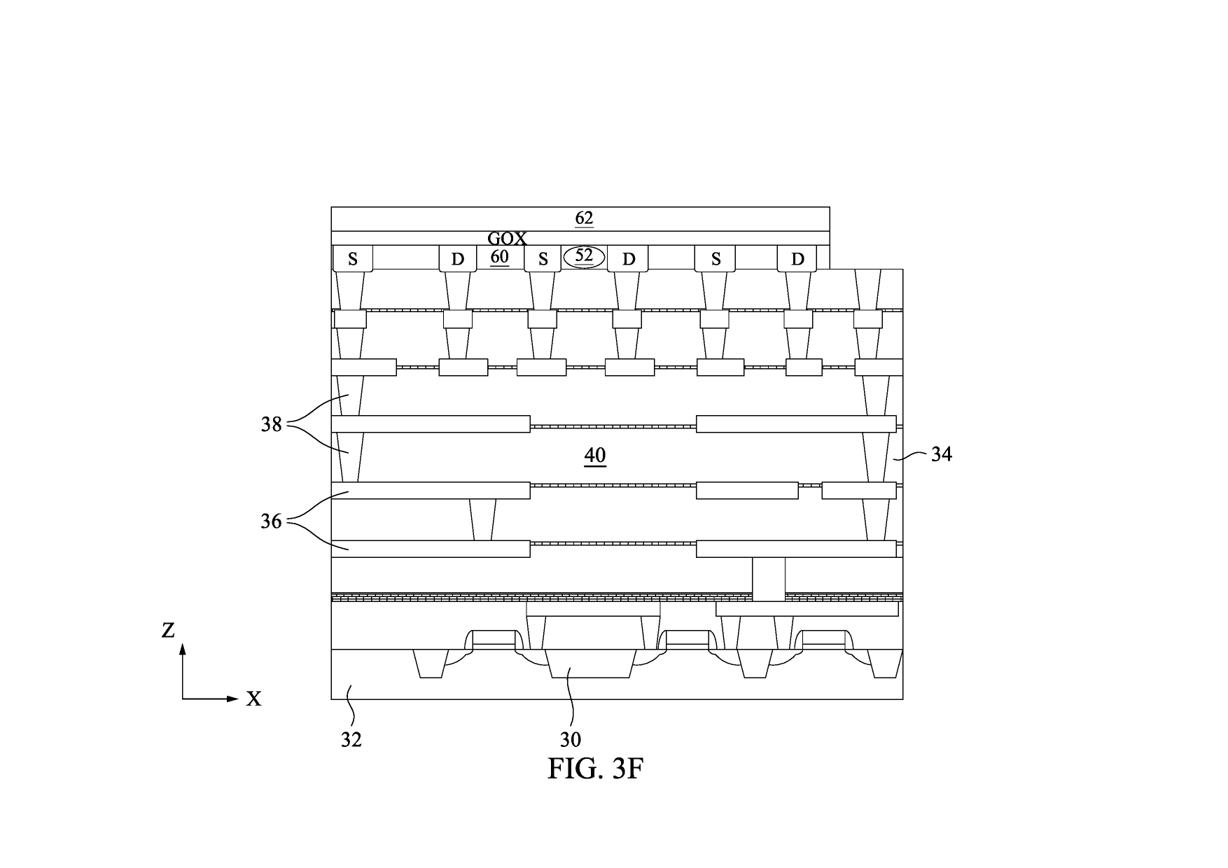

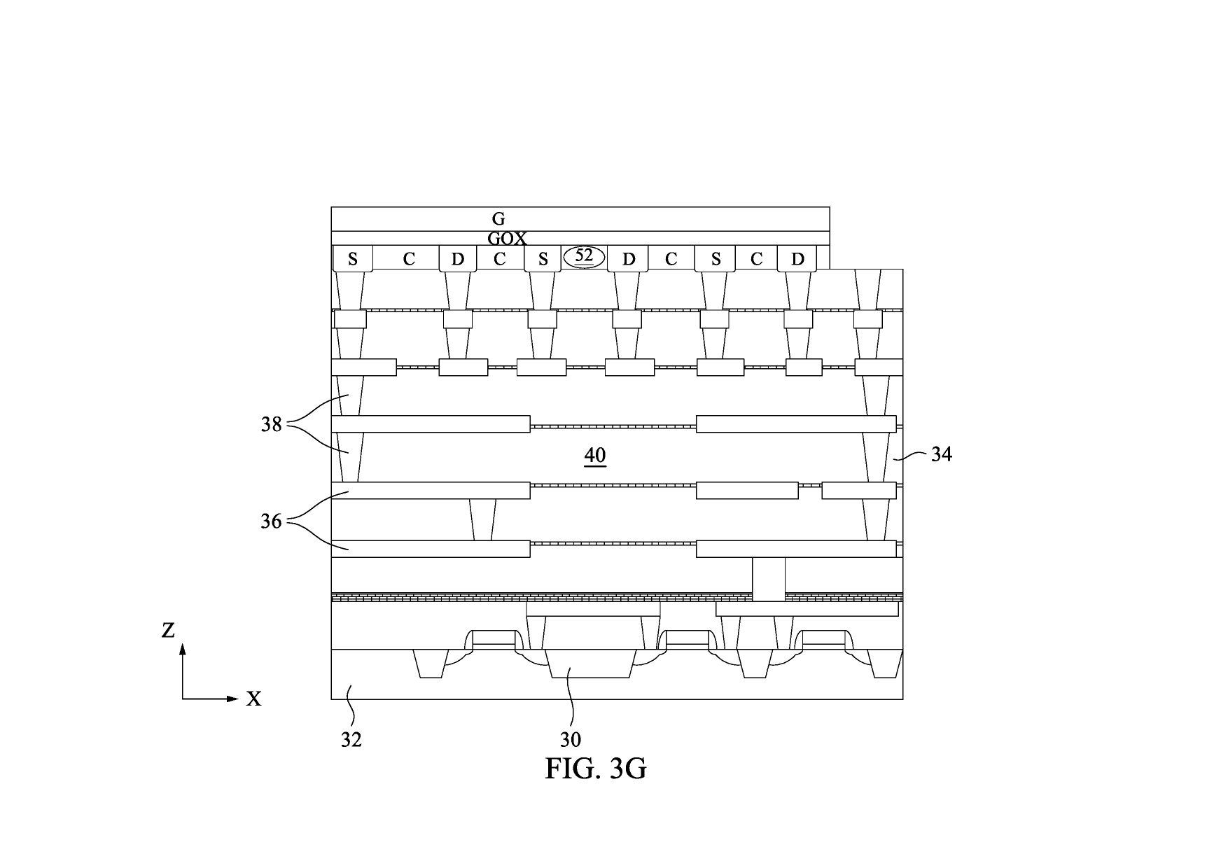

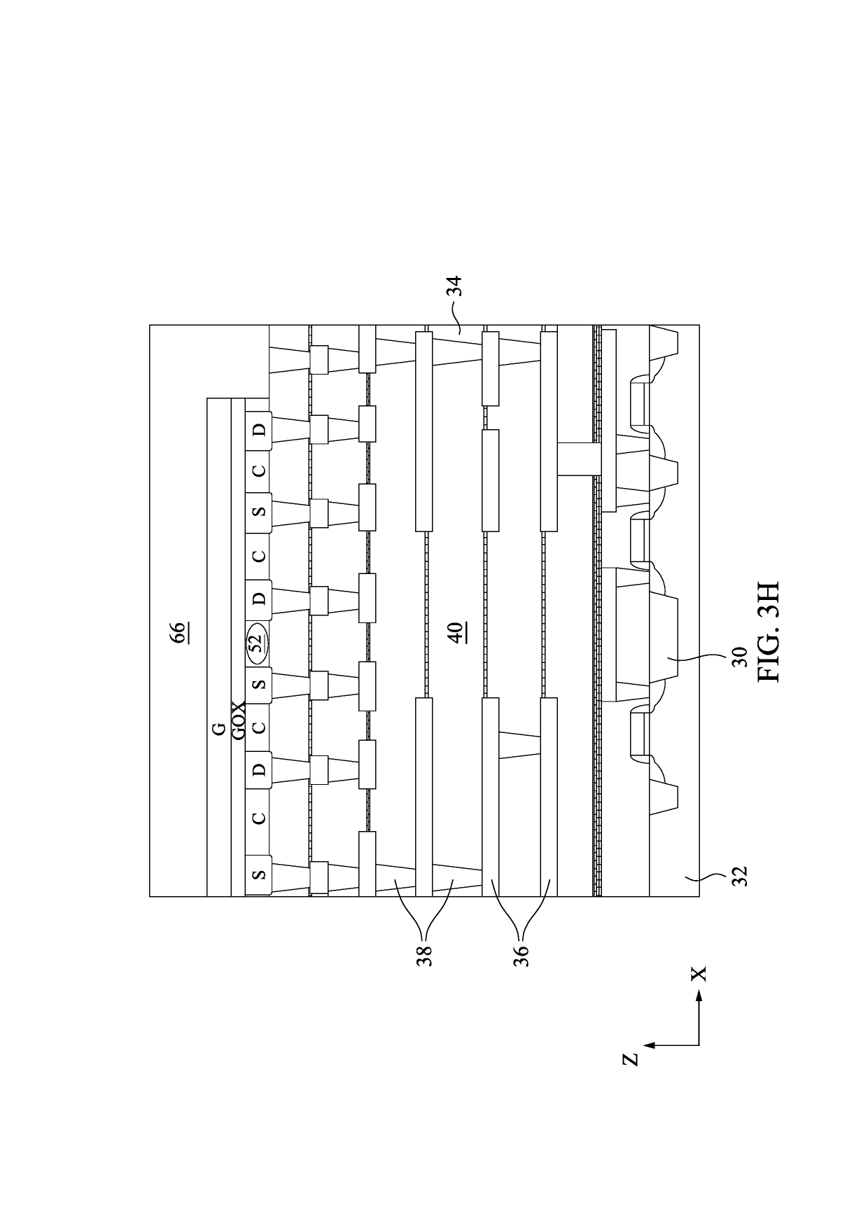

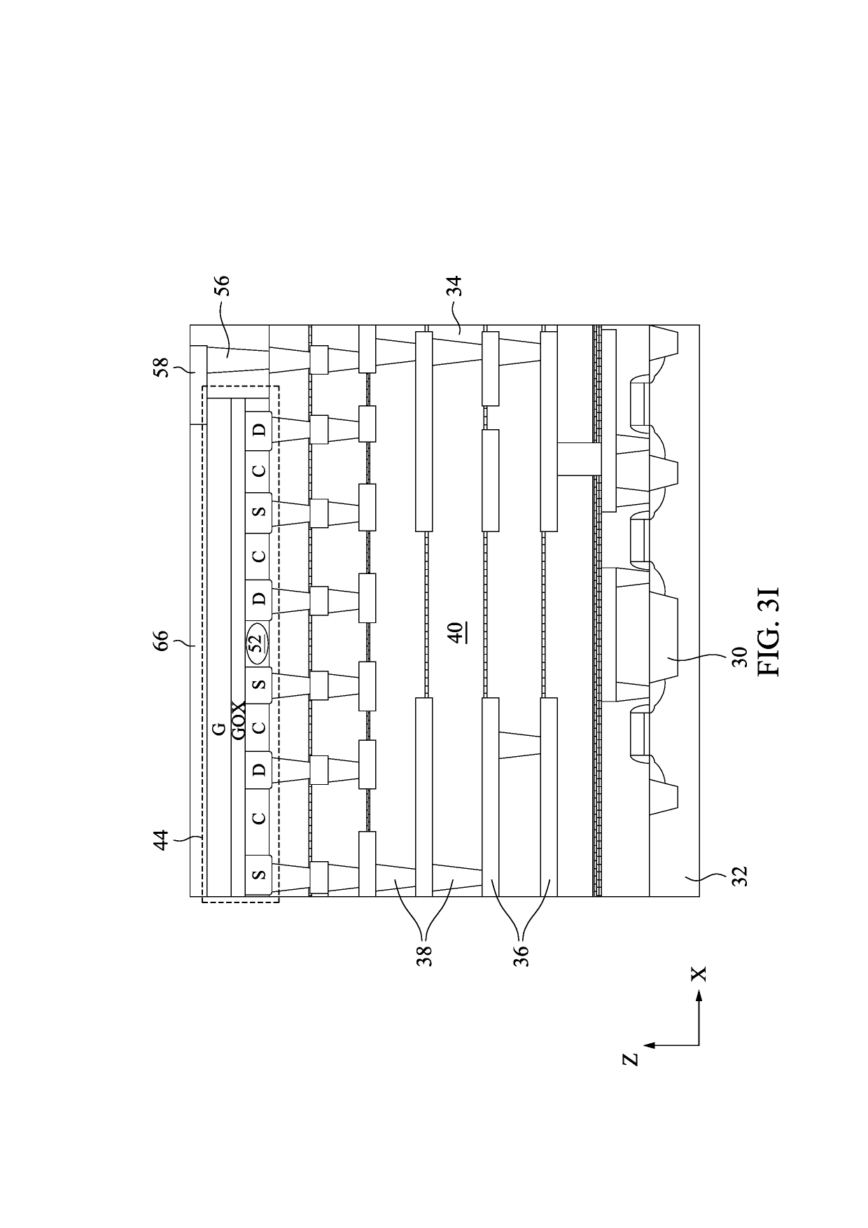

As seen in FIG. 2B, vias 38 of the metallization stack 34 are aligned to electrically contact the source and drain lines S and D to provide electrical connectivity of the source and drain lines S and D with the logic circuitry devices 30. In FIG. 2A, one such contact 54 (namely an illustrative source line contact 54 in the example of FIG. 2A) is diagrammatically indicated. In the example of FIG. 2A, the source line S (and drain line D) contacts are made at the edges of the source and drain lines S and D. FIG. 2B also shows metal routing (i.e., via opening formation in the protective oxide layer 66 which is filled to form a via 56, and deposition and patterning of a gate contact 58. While only one such contact structure 56, 58 is seen in the cut view of FIG. 3I, it will be appreciated that similar contact structures may be formed to contact each gate line G.

With reference now to FIGS. 3A, 3B, 3C, 3D, 3E, 3F, 3G, 3H, and 3I, one nonlimiting illustrative fabrication process for fabricating the IC of FIGS. 2A and 2B is described by way of cut views at cut A-A’ (see FIG. 2A) of the IC under fabrication at successive steps of the fabrication process. FIG. 3A illustrates the IC after front end-of-line (FEOL) processing to form the logic circuitry devices 30 in and/or on a semiconductor substrate 32, and at least initial back end-of-line (BEOL) processing to form the metallization stack 34 including the patterned metal layers 36 and the vias 38 embedded in the dielectric material 40. The FEOL processing can use any fabrication technology suitable for the type(s) of logic circuitry devices 30, e.g., GAA processing if the logic circuitry devices 30 include GAA transistors, MOS processing if the logic circuitry devices 30 include MOSFETs, FinFET processing if the logic circuitry devices 30 include FinFETs, and/or so forth. The BEOL processing entails iterative fabrication in which each iteration include depositing a layer of the dielectric material 40, etching photolithographically defined via openings in the dielectric layer, filling the via openings with a conductive material to form vias 38 of the layer, and depositing a metal layer and patterning it to form the patterned metal layer 36. The topmost iteration stops after filling the via openings with a conductive material to form vias 38 of the top layer and performing chemical mechanical polishing (CMP) to planarize the top surface.

The subsequent processing described with reference to FIGS. 3B-3I is performed to form the ROM transistor array 44. In some embodiments, this processing is performed at a relatively low temperature. For example, in some embodiments the formation of the ROM transistor array 44 is performed at a temperature of 450^{o}C or lower.

FIG. 3B shows the IC in-progress after deposition of an amorphous silicon layer 60. The transistor channels C and source and drain lines S and D will subsequently be formed from the amorphous silicon layer 60, which may be deposited by chemical vapor deposition (CVD) or physical vapor deposition (PVD), as nonlimiting illustrative examples. Higher temperatures can lead to undesired crystallization of the amorphous silicon layer 60 – hence, in some embodiments the amorphous silicon layer 60 is deposited at a temperature of 450^{o}C or lower. Processing performed subsequent to the deposition of the amorphous silicon layer 60 (e.g., as described below with reference to FIGS. 3C, 3D, 3E, 3F, 3G, 3H, and 3I) is also in some embodiments performed at a temperature of 450^{o}C or lower, again to avoid crystallization of the previously deposited amorphous silicon layer 60.

FIG. 3C shows the IC in-progress after selective doping of the amorphous silicon layer 60 to form the source and drain lines S and D with the desired high electrical conductivity for these regions. The dopant used to form the source and drain lines S and D may, by way of nonlimiting illustrative example, be nitrogen, phosphorous, arsenic, tin, bismuth, oxygen, nitrogen, sulfur, selenium, tellurium, fluorine, chlorine, bromine, iodine, boron, aluminum, gallium, indium, titanium, tantalum, or so forth.

As seen in FIG. 3C, vias 38 of the metallization stack 34 are aligned to electrically contact the source and drain lines S and D to provide electrical connectivity of the source and drain lines S and D with the logic circuitry devices 30. Referring back to the top view of FIG. 2A, one such contact 54 (namely an illustrative source line contact 54 in the example of FIG. 2A) is diagrammatically indicated.

Also shown in FIG. 3C is a representative targeted dopant implant 52 formed by spatially controlled (i.e., targeted) dopant implantation, which may be done at this stage of the ROM transistor array fabrication to store specific logical values in the (not yet fully fabricated) ROM transistors.

FIG. 3D shows the IC in-progress after depositing the gate oxide Gox. A deposition technique such as CVD or atomic layer deposition (ALD) may be used to deposit the gate oxide Gox, which comprises a dielectric material such as (by way of nonlimiting illustrative example) SiO₂, SiON, SiN, HfO, or a high-k dielectric material. The gate oxide Gox may in some nonlimiting illustrative embodiments have a thickness of 10-20 nanometers, although a thickness outside this range is also contemplated.

FIG. 3E shows the IC in-progress after deposition of a polycrystalline silicon layer 62 (also referred to herein as a polysilicon layer 62 or poly-Si layer 62) on the gate oxide Gox. The polycrystalline silicon layer 62 will subsequently be patterned by photolithographically controlled etching to form the gate lines G. The polycrystalline silicon layer 62 may be deposited by CVD or PVD, as nonlimiting illustrative examples, and may be deposited with doping at a level corresponding to the desired doping of the gate lines G.

FIG. 3F shows the IC in-progress after defining the area of the ROM transistor array 44. This area corresponds to the ROM transistor array footprint, and entails photolithographically controlled etching to remove portions of the layer stack (including the amorphous silicon layer 60, gate oxide Gox, and polycrystalline silicon layer 62) outside of the ROM transistor array footprint.

FIG. 3G shows the IC in-progress after photolithographically controlled etching of the remaining layer stack (including the amorphous silicon layer 60, gate oxide Gox, and polycrystalline silicon layer 62) to define the gate lines G and transistor channels C of the ROM transistor array 44.

FIG. 3H shows the IC in-progress after deposition of a protective oxide layer 66 on the surface. The oxide layer 66 is planarized by CMP. While an oxide layer is described, another type of dielectric material could be used for the layer 66.

FIG. 3I shows the final IC including the final fabricated ROM transistor array 44 after further processing including metal routing (i.e., via opening formation in the protective oxide layer 66 which is filled to form a via 56, and deposition and patterning of a gate contact 58. While only one such contact structure 56, 58 is seen in the cut view of FIG. 3I, it will be appreciated that similar contact structures may be formed to contact each gate line G.

The foregoing processing is to be understood as a nonlimiting illustrative example, and other processing workflows may be employed to fabricate the ROM transistor array 44.

In the embodiment of FIGS. 2A and 2B, the targeted dopant implants 52 applied to program values in ROM transistors implant the threshold voltage (Vt)-altering dopant dose in the channels C of the corresponding ROM transistors.

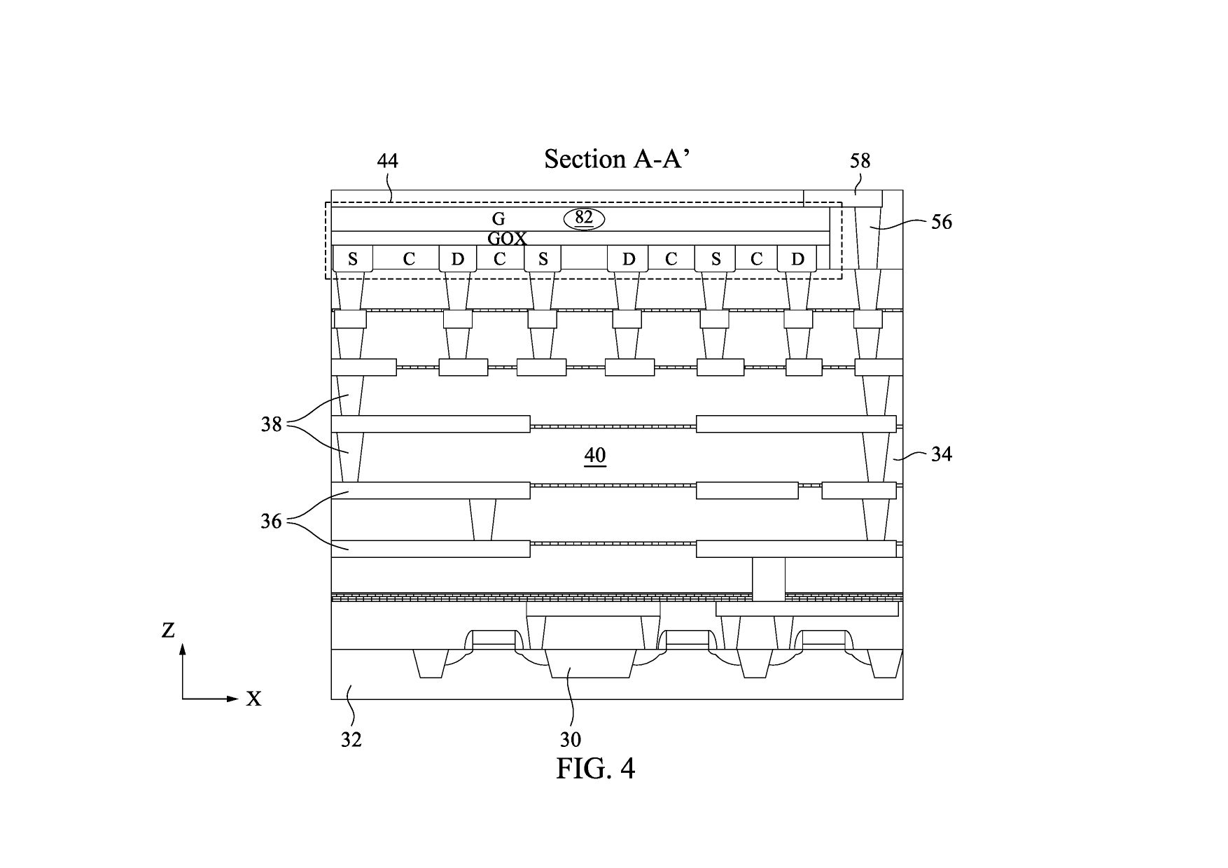

With reference now to FIG. 4, a cut view along cut A-A’ of FIG. 2A is shown according to a variant embodiment in which the targeted dopant implants 52 which implant dopant dose into the channels C of the ROM transistors are replaced by targeted dopant implants 82 which implant dopant dose into the gates G of the ROM transistors. Like the previously described targeted dopant implants 52 which implant dopant dose into the channels C, the targeted dopant implants 82 into the gates G also have the desired effect of modifying the threshold voltage (Vt) of the ROM transistor.

Although not illustrated, it is also contemplated for the targeted dopant implants for adjusting the threshold voltage (Vt) of selected ROM transistors may have a broader implanted dopant profile which implants dopant dose into both the gate G and channel C of the ROM transistor. Moreover, as the dopant profile of an implanted dopant dose has finite spatial spread, the targeted dopant implants 52 using implantation parameters (e.g., acceleration energy peak) designed to implant dopant dose into the channels C may also implant a portion of the dopant dose (e.g., a tail of the dopant profile) into the gate G. Similarly, the targeted dopant implants 82 which are designed to implant dopant dose into the gates G may also implant a portion of the dopant dose (e.g., a tail of the dopant profile) into the channel C.

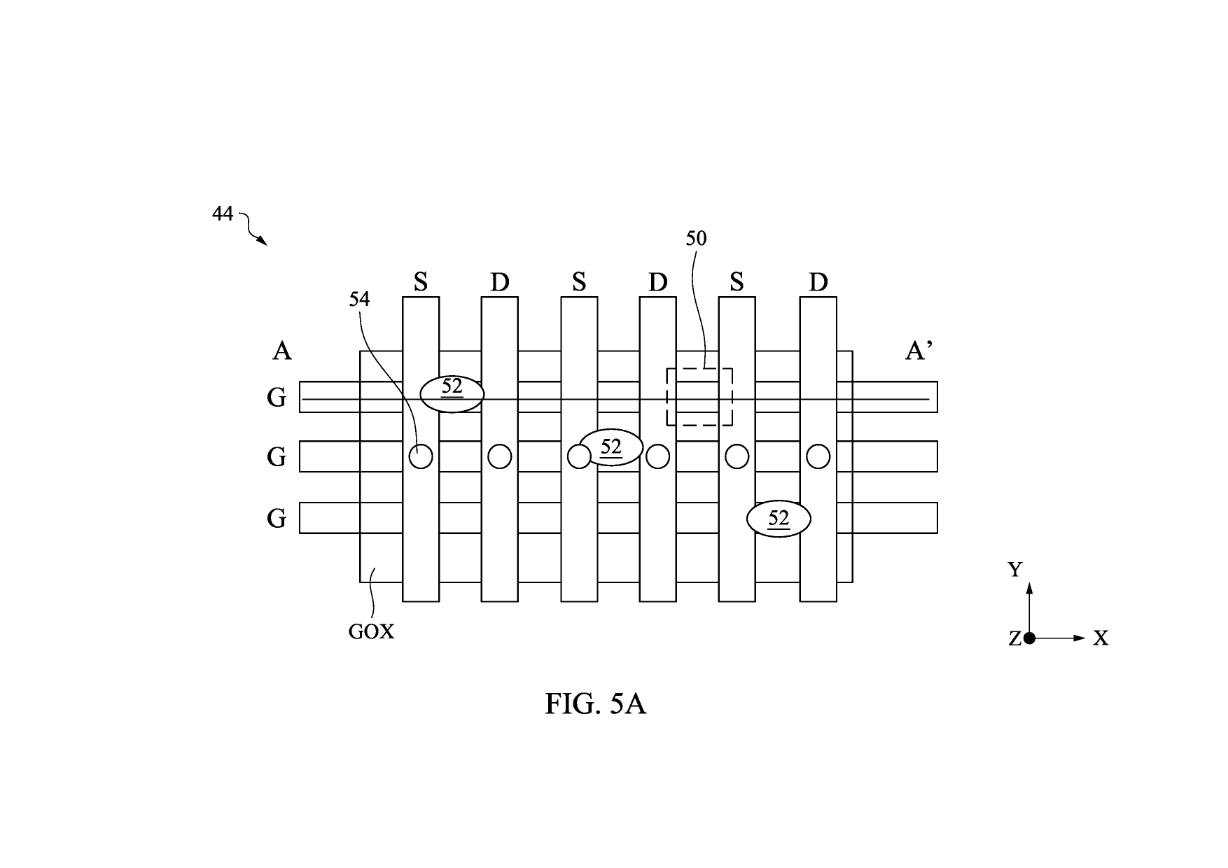

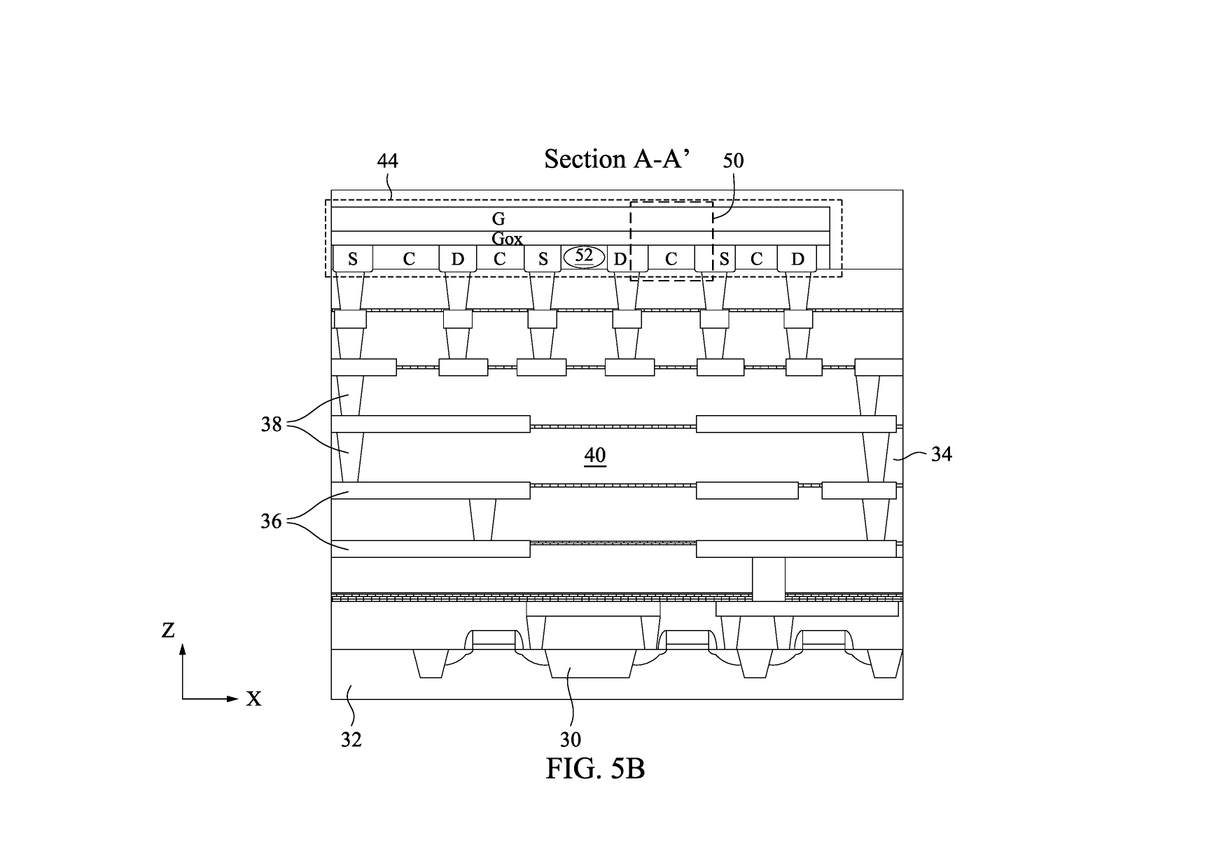

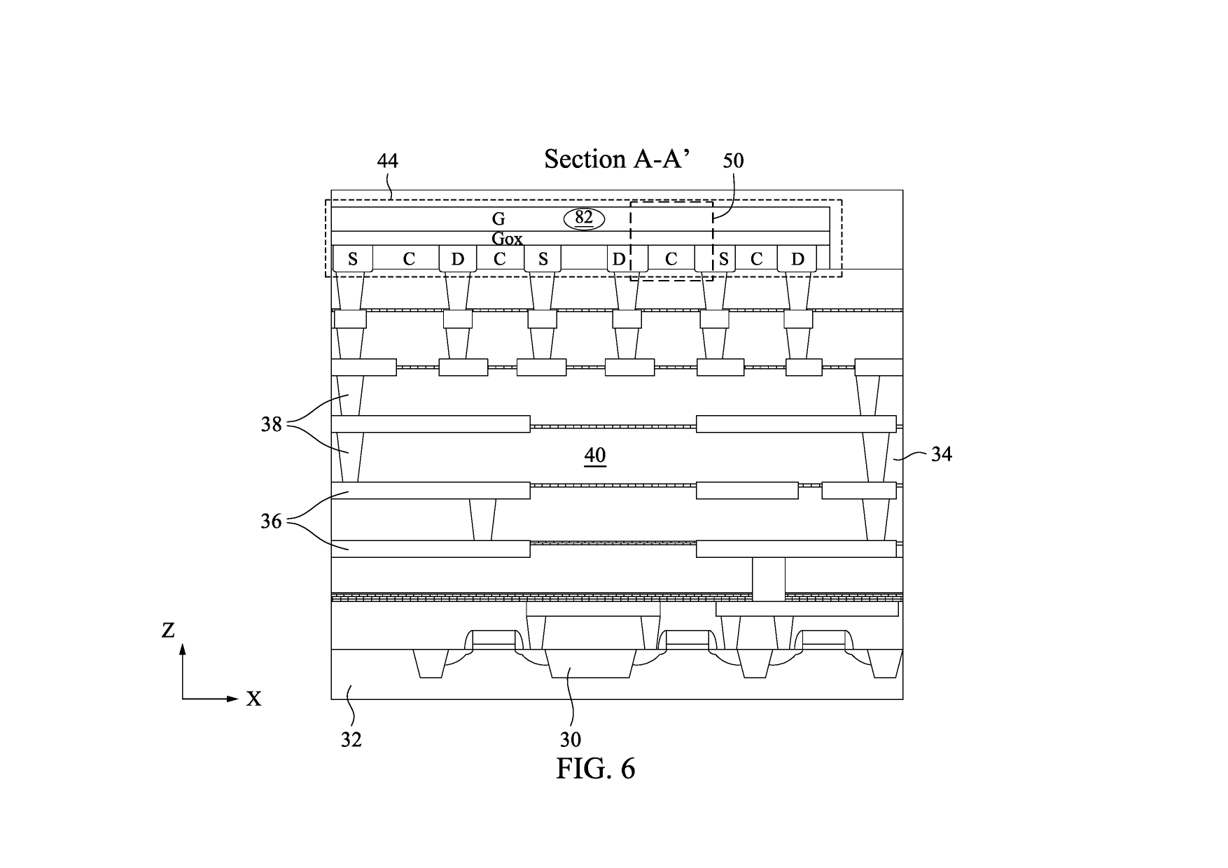

FIGS. 5A and 5B diagrammatically illustrate top and cut views, respectively, of an IC with compact configuration of FIGS. 1C and 1D, in accordance with another embodiment. FIG. 5B is a cut taken along the Cut plane A-A’ indicated in FIG. 5A. FIG. 5B includes the previously described logic circuitry devices 30 formed in and/or on the semiconductor substrate 32, the metallization stack 34 disposed on the semiconductor substrate 32 (and more particularly on the logic circuitry devices 30) which includes the patterned metal layers 36 and vias 38 embedded in the dielectric material 40, and the ROM transistor array 44. As in the embodiment of FIGS. 2A and 2B, the ROM transistor array 44 of FIGS. 5A and 5B includes the transistor channels C, the source lines S and the drain lines D, the gate oxide Gox, and the gate lines G. As in the embodiment of FIGS. 2A and 2B, the channels C, source lines S, and drain lines D of the ROM transistor array 44 of FIGS. 5A and 5B are formed from an amorphous silicon (a-Si) layer, with the source and drain lines S and D being formed by targeted doping of the amorphous silicon layer to make the source and drain lines S and D more electrically conductive than the remainder of the amorphous silicon layer which forms the channels C. The gate oxide Gox is deposited on the amorphous silicon layer, and comprises a dielectric material. The gate lines G in some embodiments comprise a polycrystalline silicon layer disposed on the gate oxide Gox and patterned to form the gate lines. As seen in the top view of FIG. 5A, the gate lines G are parallel with the X-direction while the source and drain lines S and D are parallel with the transverse Y-direction. The source lines S and drain lines D are parallel with each other, the gate lines G are transverse (i.e., orthogonal) to the source and drain lines S and D, and the transistor channels C are oriented along the X-direction parallel with the gate lines G, with each transistor channel C having a corresponding segment of an aligned gate line G disposed proximate to it, and spaced apart by the gate oxide Gox. As in the embodiment of FIGS. 2A and 2B, the ROM transistor array 44 of FIGS. 5A and 5B is disposed in an X-Y plane, with each ROM transistor connected with a source line S, a drain line D, and having a gate comprising the corresponding segment of an aligned gate line G spaced apart therefrom by the gate oxide Gox. Again, one illustrative ROM transistor 50 of the ROM transistor array 44 is indicated by a dashed box in FIGS. 5A and 5B. As in the embodiment of FIGS. 2A and 2B, as seen in FIG. 5B a given ROM transistor is programmed to store either a logical “1” or a logical “0” by whether its threshold voltage (Vt) is adjusted by a targeted dopant implant 52 that deposits implanted dopant in the channel C of the ROM transistor. FIG. 6A shows three examples of targeted dopant implants 52 to program values in a corresponding three ROM transistors.

The embodiment of FIGS. 5A and 5B differs from the embodiment of FIGS. 2A and 2B in that it has a different contacting arrangement for electrically connecting the ROM transistor array 44 with the logic circuitry devices 30 formed in and/or on a semiconductor substrate 32. In the embodiment of FIGS. 5A and 5B, the source and drain contacts 54 are made in a middle part of the corresponding source and drain lines S and D. In FIG. 5A, six such contacts 54 are diagrammatically indicated. Comparing the cut views of FIGS. 5B and 2B, the cut view of FIG. 5B does not show the metal routing 56, 58 connecting to a gate line G. For example, the gate lines may be contacted at their edges (outside of the cut plane A-A’).

With reference now to FIG. 6, a cut view along cut A-A’ of FIG. 5A is shown according to a variant embodiment in which the targeted dopant implants 52 which implant dopant dose into the channels C of the ROM transistors are replaced by targeted dopant implants 82 which implant dopant dose into the gates G of the ROM transistors. The targeted dopant implants 82 into the gates G also have the desired effect of modifying the threshold voltage (Vt) of the ROM transistor.

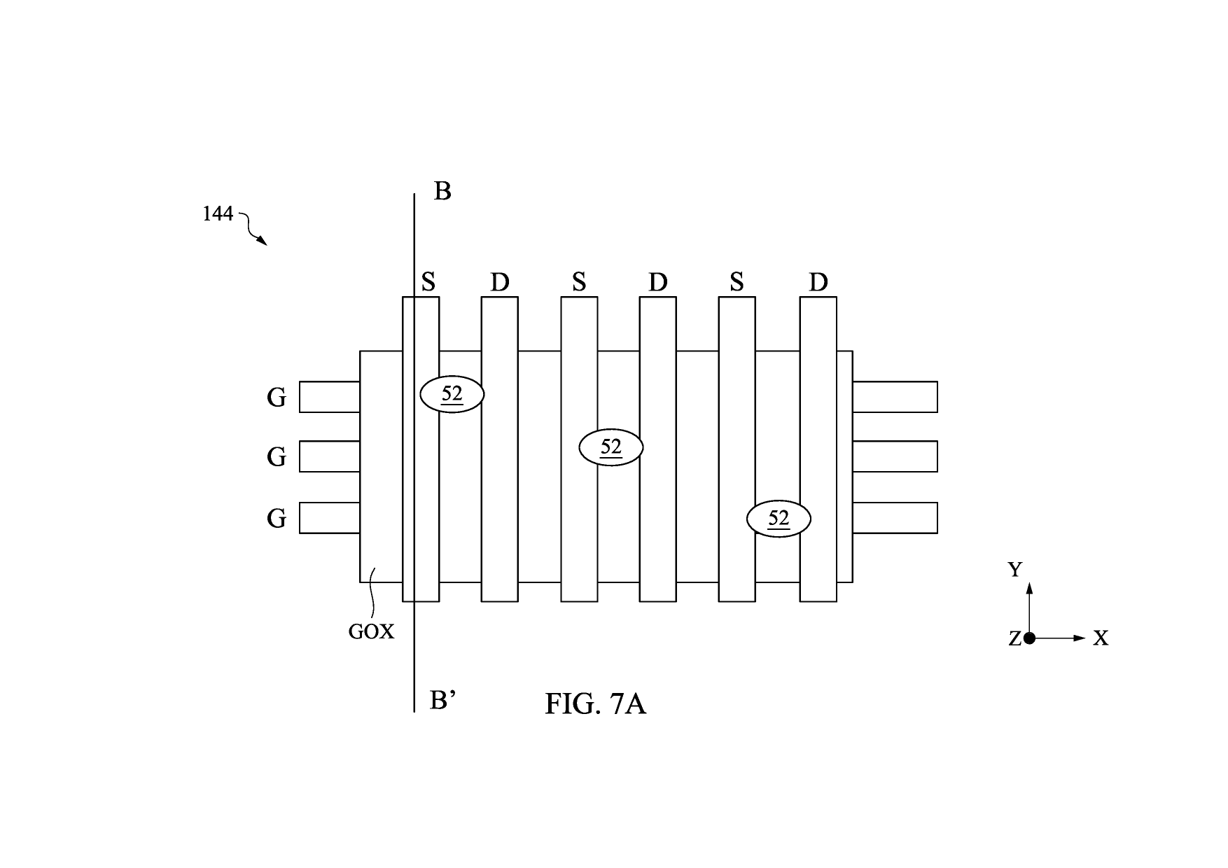

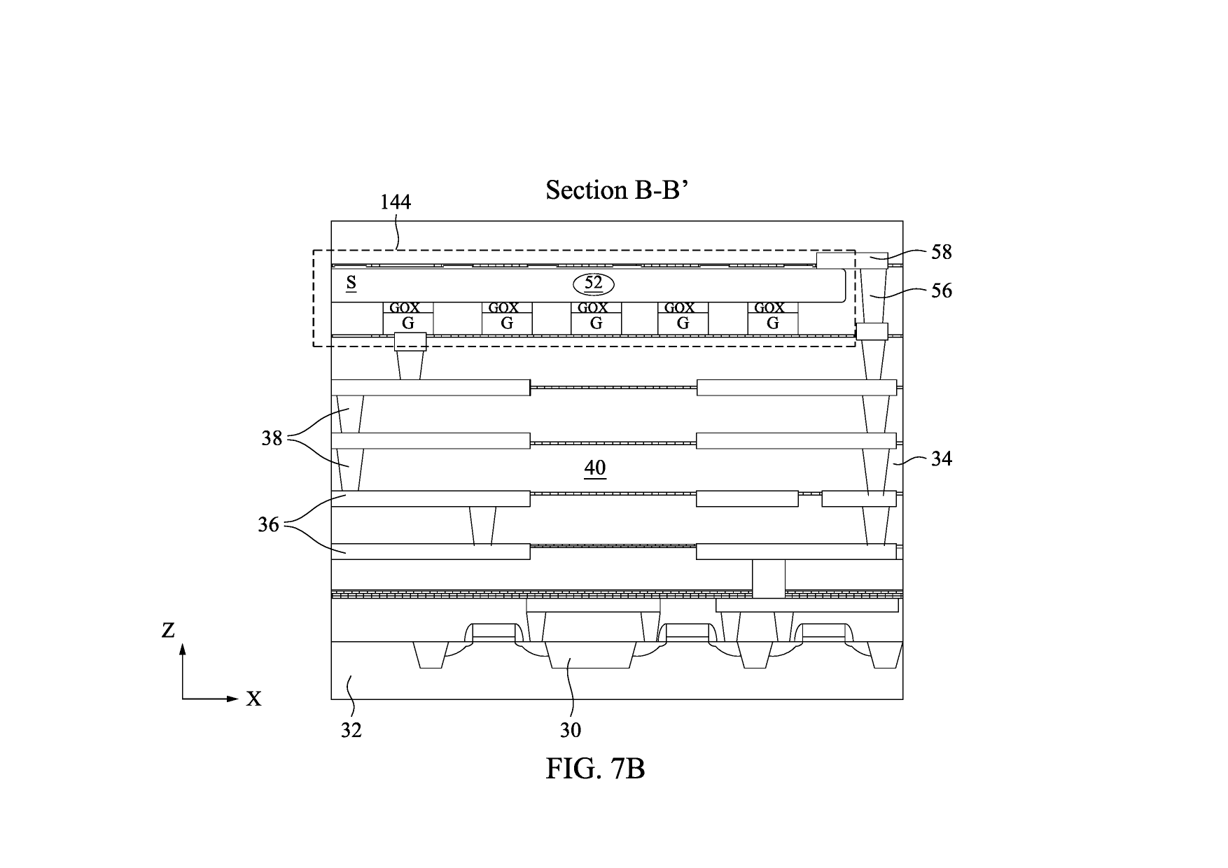

FIGS. 7A and 7B diagrammatically illustrate top and cut views, respectively, of an IC with compact configuration of FIGS. 1C and 1D, in accordance with another embodiment. FIG. 7B is a cut taken along the Cut plane B-B’ through a source line S as indicated in FIG. 7A. The cut plane B-B’ is thus a Y-Z plane passing through one of the source lines S. As seen in FIG. 7B, the IC of the embodiment of FIGS. 7A and 7B includes the previously described logic circuitry devices 30 formed in and/or on the semiconductor substrate 32, and the metallization stack 34 which again includes the patterned metal layers 36 and vias 38 embedded in the dielectric material 40.

The embodiment of FIGS. 7A and 7B differ from the previous embodiments by employing a different ROM transistor array 144, in which the order of deposition of the amorphous silicon layer 60 and the polycrystalline silicon layer 62 (see FIGS. 3B and 3E) is reversed. Consequently, as seen in FIG. 7B the gate lines G are disposed below (i.e., underneath) the gate oxide Gox, and the source and gate lines S and D (one source line S being visible in cut view B-B’) and the transistor channels (not visible in FIG. 7B but oriented parallel with, and located above, the gate lines G). As in the previous embodiments, the gate lines G are formed from the (here first-deposited) polycrystalline silicon layer, and the transistor channels C and the source and drain lines S and D are formed from the (here second-deposited) amorphous silicon layer.

The processing of FIGS. 3A-3I can be employed to fabricate the IC of FIGS. 7A and 7B, but with the deposition of the polycrystalline silicon layer (FIG. 3E) being performed first, followed by deposition of the gate oxide Gox (FIG. 3D, here deposited on the polycrystalline silicon layer 62), followed by deposition and processing of the amorphous silicon layer (FIG. 3B) to form the source and drain lines S and D and transistor channels C. In some embodiments the amorphous silicon layer is deposited at a temperature of 450^{o}C or lower to avoid crystallization of the amorphous silicon layer 60, and processing performed subsequent to the deposition of the amorphous silicon layer is also in some embodiments performed at a temperature of 450^{o}C or lower, to avoid crystallization of the previously deposited amorphous silicon layer 60. In the embodiment of FIGS. 7A and 7B, since the polycrystalline silicon layer forming the gate lines G and the gate oxide layer Gox are deposited before the deposition of the amorphous silicon layer, the deposition of the polycrystalline silicon layer and the gate oxide layer Gox can optionally be performed at a higher temperature. The illustrative example of FIG. 7B includes the contact structure 56, 58 of the embodiment of FIG. 2B; however, other contact arrangements are contemplated.

In the following, some further embodiments are described.

In a nonlimiting illustrative embodiment, a method is disclosed of fabricating an integrated circuit. The method includes: forming logic circuitry devices in and/or on a semiconductor substrate; forming a metallization stack on the semiconductor substrate, the metallization stack comprising patterned metal layers and vias embedded in a dielectric material; and forming a read-only memory (ROM) transistor array on the metallization stack, the ROM transistor array being electrically connected with vias of the metallization stack.

In a nonlimiting illustrative embodiment, a method is disclosed of fabricating an integrated circuit. The method includes: forming logic circuitry devices in and/or on a semiconductor substrate; forming a metallization stack on the semiconductor substrate, the metallization stack comprising patterned metal layers and vias embedded in a dielectric material; and forming a read-only memory (ROM) transistor array on the metallization stack, the ROM transistor array being electrically connected with vias of the metallization stack. A footprint of the ROM transistor array at least partly overlaps a footprint of the logic circuitry devices.

In a nonlimiting illustrative embodiment, a method is disclosed of fabricating a ROM transistor array on a metallization stack of an integrated circuit. The method comprises: disposing an amorphous silicon layer on the metallization stack; doping the amorphous silicon layer to form source and drain lines of the ROM transistor array; disposing a gate dielectric layer on the amorphous silicon layer; disposing a polycrystalline silicon layer on the gate dielectric layer; and processing the polycrystalline silicon layer to form polycrystalline silicon gate lines of the ROM transistor array.

In a nonlimiting illustrative embodiment, an integrated circuit comprises: logic circuitry devices disposed in and/or on a semiconductor substrate; a metallization stack disposed on the logic circuitry devices, the metallization stack comprising patterned metal layers and vias embedded in a dielectric material; and a ROM transistor array disposed on the metallization stack with the metallization stack interposed between the ROM transistor array and the logic circuitry devices and the metallization stack electrically connecting the ROM transistor array and the logic circuitry devices.

In a nonlimiting illustrative embodiment, a method for fabricating an integrated circuit includes forming logic circuitry devices in and/or on a semiconductor substrate. A metallization stack is formed on the semiconductor substrate. The metallization stack includes patterned metal layers and vias embedded in a dielectric material. A read-only memory (ROM) transistor array is formed on the metallization stack. The ROM transistor array is electrically connected with vias of the metallization stack. The ROM transistor array may include transistor channels and source and drain lines formed from an amorphous silicon layer that is deposited at a temperature of 450^{o}C or lower. ROM transistor array fabrication steps performed after depositing the amorphous silicon layer may also be performed at a temperature of 450^{o}C or lower.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of fabricating an integrated circuit, the method comprising:
forming logic circuitry devices in and/or on a semiconductor substrate;
forming a metallization stack on the semiconductor substrate, the metallization stack comprising patterned metal layers and vias embedded in a dielectric material; and
forming a read-only memory (ROM) transistor array on the metallization stack, the ROM transistor array being electrically connected with vias of the metallization stack;
wherein a footprint of the ROM transistor array at least partly overlaps a footprint of the logic circuitry devices.

2. The method of claim 1, wherein the forming of the ROM transistor array includes:
disposing an amorphous silicon layer on the metallization stack;
doping the amorphous silicon layer to form source and drain lines of the ROM transistor array;
disposing a gate dielectric layer on the amorphous silicon layer; and
forming gate lines of the ROM transistor array on the gate dielectric layer.

3. The method of claim 2, wherein the gate lines comprise polycrystalline silicon.

4. The method of claim 3, wherein the forming of the ROM transistor array further includes:
storing data in the ROM transistor array by implanting a dopant into the polycrystalline silicon to modify threshold voltages of preselected ROM transistors of the ROM transistor array.

5. The method of claim 3, wherein the forming of the ROM transistor array further includes:
storing data in the ROM transistor array by implanting a dopant into the amorphous silicon layer to modify threshold voltages of preselected ROM transistors of the ROM transistor array.

6. The method of claim 2, wherein the forming of the ROM transistor array is performed at a temperature of 450^{o}C or lower.

7. The method of claim 1, wherein the forming of the ROM transistor array includes storing data in the ROM transistor array by implanting a dopant to modify threshold voltages of preselected ROM transistors of the ROM transistor array.

8. The method of claim 1, wherein the forming of the ROM transistor array includes:
forming gate lines of the ROM transistor array on the metallization layer;
disposing a gate dielectric layer on the gate lines; and
disposing an amorphous silicon layer on the metallization stack; and
doping the amorphous silicon layer to form source and drain lines of the ROM transistor array.

9. The method of claim 1, wherein:
the logic circuity devices are formed in front end-of-line (FEOL) processing; and
the ROM transistor array is formed in back end-of-line (BEOL) processing.

10. The method of claim 1, wherein the footprint of the ROM transistor array is equal to or entirely inside the footprint of the logic circuitry devices.

11. A method of fabricating a read-only memory (ROM) transistor array on a metallization stack of an integrated circuit, the method comprising:
disposing an amorphous silicon layer on the metallization stack;
doping the amorphous silicon layer to form source and drain lines of the ROM transistor array;
disposing a gate dielectric layer on the amorphous silicon layer;
disposing a polycrystalline silicon layer on the gate dielectric layer; and
processing the polycrystalline silicon layer to form polycrystalline silicon gate lines of the ROM transistor array.

12. The method of claim 11, further comprising:
storing data in the ROM transistor array by implanting a dopant into the polycrystalline silicon to modify threshold voltages of preselected ROM transistors of the ROM transistor array.

13. The method of claim 11, further comprising:
storing data in the ROM transistor array by implanting a dopant into the amorphous silicon layer to modify threshold voltages of preselected ROM transistors of the ROM transistor array.

14. The method of claim 11, wherein the disposing of the amorphous silicon layer, the disposing of the gate dielectric layer, and the disposing and processing of the polycrystalline silicon layer are performed at a temperature of 450^{o}C or lower.

15. The method of claim 11, further comprising:
depositing a dielectric layer on the polycrystalline silicon layer; and
forming one or more metal connections in and/or on the dielectric layer that electrically connect the polycrystalline silicon gate lines of the ROM transistor array with the metallization stack.

16. An integrated circuit comprising:
logic circuitry devices disposed in and/or on a semiconductor substrate;
a metallization stack disposed on the logic circuitry devices, the metallization stack comprising patterned metal layers and vias embedded in a dielectric material; and
a read-only memory (ROM) transistor array disposed on the metallization stack with the metallization stack interposed between the ROM transistor array and the logic circuitry devices and the metallization stack electrically connecting the ROM transistor array and the logic circuitry devices.

17. The integrated circuit of claim 16, further comprising:
a dielectric layer disposed on the ROM transistor array, the dielectric layer including at least one electrical pathway also electrically connecting the ROM transistor array and the logic circuitry devices.

18. The integrated circuit of claim 16, wherein the ROM transistor array includes dopant implant regions encoding data in the ROM transistor array.

19. The integrated circuit of claim 18, wherein the ROM transistor array comprises amorphous silicon and the dopant implant regions encoding the data in the ROM transistor array are implanted in the amorphous silicon.

20. The integrated circuit of claim 18, wherein the ROM transistor array includes polycrystalline silicon gate lines, and the dopant implant regions encoding the data in the ROM transistor array are implanted in the polycrystalline silicon gate lines.
